(19) United States
(12) Patent Application Publication
(10) Pub. No.: US 2025/0372509 A1
(43) Pub. Date: Dec. 4, 2025

(54) MICROELECTRONIC DEVICE PACKAGE WITH HYBRID ISOLATION LAMINATE

(71) Applicant: Texas Instruments Incorporated, Dallas, TX (US)

(72) Inventors: Anindya Poddar, Sunnyvale, CA (US); Chun Ping Lo, Allen, TX (US); Vivek Arora, San Jose, CA (US)

(21) Appl. No.: 18/679,587

(22) Filed: May 31, 2024

(51) Int. Cl. H01L 23/522; H01L 23/00; H01L 23/495; H01L 25/065

(52) U.S. Cl. CPC H01L 23/5227; H01L 23/4951; H01L 23/49575; H01L 24/05; H01L 24/13; H01L 24/97; H01L 25/0652; H01L 2224/05009; H01L 2224/05025; H01L 2224/13005; H01L 2224/13025; H01L 2224/97; H01L 2924/0665; H01L 2924/1206; H01L 2924/1304; H01L 2924/182

(57) ABSTRACT

An example microelectronic device package includes: a substrate, including core trace level conductor layers on opposite sides of a planar dielectric core, and prepreg layers of resin impregnated glass cloth over the trace level conductor layers on the opposite sides of the planar dielectric core. A layer of resin thermoset film is formed over one of the prepreg layers, the layer of resin thermoset film cured to form a solid dielectric film layer. Film layer conductive vias extend through the solid dielectric film layer. A surface level conductor layer is formed over the solid dielectric film layer on a surface of the solid dielectric film layer. A first semiconductor die and a second die are mounted on the surface of the solid dielectric film layer.

### TECHNICAL FIELD

This disclosure relates generally to microelectronic device packages, and more particularly to microelectronic device packages including semiconductor dies mounted on a laminate substrate with isolation.

### BACKGROUND

Processes for producing microelectronic device packages include mounting one or more semiconductor dies to a substrate and covering the electronic devices with a dielectric material, such as a mold compound, to form the packaged devices.

Incorporating passive components such as capacitors, inductors, and coils with semiconductor devices in a microelectronic device package is often desirable. Power package applications include packaging devices together in a system using passive components such as inductors and coils with semiconductor dies to increase performance and reduce board area, and to make the microelectronic device package with the passives needed for a normal configuration as a single component, which increases ease of use and reduces board design time. Often a passive component is mounted next to or mounted on or over a completely packaged semiconductor device.

In certain applications, isolation is required between terminals for a microelectronic device package. Some terminals of the microelectronic device package are configured for connection to a first voltage domain and other terminals of the microelectronic device package are configured for connection to a second voltage domain, the two voltage domains have isolated grounds. An example application is a DC-DC converter for a power supply to deliver power a load. Because the two voltage domains are isolated, high voltage potentials of hundreds or thousands of volts can occur between the two voltage domains. To safely transfer current from one voltage domain to the other, for example in the DC-DC converter application, electrical isolation between devices coupled to one domain and devices coupled to the other domain is required. In example DC-DC applications, a transformer can be used, or a capacitive coupling can be used, to transfer energy or signals across the electrical isolation barrier between the two voltage domains.

Prior approaches for a substrate that provides the needed isolation include the use of expensive printed circuit board (PCB) package substrates, which are sometimes used inside a molded microelectronic device package with mold compound covering the semiconductor devices and the passive components. Making molded microelectronic device packages including electrical isolation that are efficient and cost-effective, including both semiconductor dies and passive components within the microelectronic device packages, remains challenging.

### SUMMARY

In a described example, a method includes: forming a substrate by patterning core trace level conductor layers on opposite sides of a dielectric core; depositing prepreg layers comprising resin impregnated glass cloth over the core trace level conductor layers on the opposite sides of the dielectric core, and curing the prepreg layers to form layers of solid prepreg dielectric material; forming openings in locations corresponding to prepreg vias in the layers of solid prepreg dielectric material using a laser drilling or a mechanical drilling process; forming conductive prepreg vias in the openings by filling the openings with conductor material; and forming prepreg trace level conductor layers over the layers of solid prepreg dielectric material. A layer of resin thermoset film is formed over one of the layers of solid prepreg dielectric material on the substrate, and the layer of resin thermoset film is cured to form a solid dielectric film layer. Openings are formed in the solid dielectric film layer at locations corresponding to film layer conductive vias using a laser drilling or mechanical drilling process. Film layer conductive vias are formed by filling the openings in the solid dielectric film layer with conductor material. Another trace level conductor layer is formed over the solid dielectric film layer.

In a further described example, a method for forming a microelectronic device package includes: forming a substrate by: patterning core trace level conductor layers on opposite sides of a planar dielectric core, forming prepreg layers of resin impregnated glass cloth over the core trace level conductor layers on the opposite sides of the planar dielectric core, curing the prepreg layers to form layers of solid dielectric prepreg material, forming openings in locations corresponding to prepreg vias in the layers of solid dielectric prepreg material using a laser drilling or mechanical drilling process, forming conductive prepreg vias by filling the openings with conductor material, and forming prepreg trace level conductors over the layers of solid dielectric prepreg material on opposite sides of the planar dielectric core. A layer of resin thermoset film is formed over the prepreg trace level conductor layers over one of the layers of solid dielectric prepreg material. The method continues by curing the layer of resin thermoset film to form a solid dielectric film layer and forming openings in locations corresponding to conductive film vias in the solid dielectric film layer using a laser drilling or mechanical drilling process. Conductive film vias are formed in the openings in the solid dielectric film layer by filling the openings with conductor material. Another trace level conductor layer is formed over the solid dielectric film layer by patterning a conductor layer on an exposed surface of the solid dielectric film layer. A first semiconductor die and a second semiconductor die are mounted over the solid dielectric film layer. The substrate is mounted to a first set of conductive leads and to a second set of conductive leads of a package substrate by forming solder joints. The method completes by covering the substrate, the solid dielectric film layer, the first semiconductor die, the second semiconductor die, portions of the first set of conductive leads, and portions of the second set of conductive leads with mold compound.

In a described example, a microelectronics device package includes: a substrate, comprising core trace level conductor layers on opposite sides of a planar dielectric core, prepreg layers of resin impregnated glass cloth over the trace level conductor layers on the opposite sides of the planar dielectric core, conductive prepreg vias extending through the prepreg layers to the core trace level conductor layers on opposite sides of the planar dielectric core, and prepreg trace level conductors over the prepreg layers and contacting the conductive prepreg vias. A layer of resin thermoset film is formed over the prepreg trace level conductor layers over one of the prepreg layers, the layer of resin thermoset film cured to form a solid dielectric film layer. Film layer conductive vias are extending through the solid dielectric film layer. Another surface level conductor layer formed over the solid dielectric film layer on the surface of the solid dielectric film layer. A first semiconductor die and a second die flip chip are mounted on the surface of the solid dielectric film layer. The substrate is mounted to a first set of conductive leads and to a second set of conductive leads of a package substrate by solder joints. A first coil and a second coil are formed from conductor layers that are ones of the core trace level conductor layers, the prepreg trace level conductor layers, or the another trace level conductor layer, the first coil and the second coil spaced from one another by dielectric material and electrically isolated from one another. The substrate, the solid dielectric film layer, the first semiconductor die and the second semiconductor die, portions of the first set of conductive leads, and portions of the second set of conductive leads covered with mold compound.

### BRIEF DESCRIPTION OF THE DRAWINGS

FIGS. 1A-1B illustrate, in a projection view and a close-up projection view, respectively, semiconductor dies on a semiconductor wafer and an individual semiconductor die.

FIGS. 2A-2B illustrate, in a top side projection view and a rear side projection view, respectively, a microelectronic device package of an example arrangement.

FIG. 3 illustrates, in a block diagram, a circuit implementing a DC-DC converter which can be packaged in a microelectronic device package of an arrangement.

FIGS. 4A-4C illustrate, in cross-sectional views, portions of a microelectronic device package of an example arrangement.

FIGS. 5A-5G illustrate, in a series of cross-sectional views, selected steps for forming a hybrid isolation laminate for use with the arrangements.

FIGS. 6A-6D illustrate, in additional cross-sectional views, selected steps for forming microelectronic device package of the arrangements.

FIGS. 7A-7B illustrate, in a flow diagram, selected steps of a method for forming a multilayer package substrate for use in example arrangements.

### DETAILED DESCRIPTION

Corresponding numerals and symbols in the different figures generally refer to corresponding parts, unless otherwise indicated. The figures are not necessarily drawn to scale.

Elements are described herein as “coupled.” The term “coupled” includes elements that are directly connected and elements that are indirectly connected, and elements that are electrically connected even with intervening elements or wires are coupled.

The term “semiconductor device” is used herein. A semiconductor device can be a discrete semiconductor device such as a bipolar transistor, a few discrete devices such as a pair of power FET switches fabricated together on a single semiconductor die, or a semiconductor device can be an integrated circuit with multiple semiconductor devices such as the multiple capacitors in an A/D converter. The semiconductor device can include passive devices such as resistors, inductors, filters, sensors, or active devices such as transistors. The semiconductor device can be an integrated circuit with hundreds or thousands of transistors coupled to form a functional circuit, for example a microprocessor or memory device. When semiconductor devices are fabricated on a semiconductor wafer and then individually separated from the semiconductor wafer, the individual units are referred to as “semiconductor dies.” A semiconductor die is also a semiconductor device.

The term “passive component” is used herein. As used herein, a passive component is a component without active devices, for example, a resistor, capacitor, inductor, coil, diode, or sensor. Examples useful in the arrangements include capacitors, resistors, inductors, transformers, or coils.

The term “microelectronic device package” is used herein. As used herein, a microelectronic device package has at least one semiconductor die electrically coupled to terminals and has a package body that protects and covers the semiconductor die. The microelectronic device package can include additional semiconductor dies or additional elements. For example, in example arrangements passive components are included. In example arrangements, multiple semiconductor dies can be packaged together with a hybrid isolation laminate. The semiconductor die or dies is/are mounted to the hybrid isolation laminate, the hybrid isolation laminate is then mounted to a substrate that provides conductive leads; a portion of the conductive leads form the terminals for the microelectronic device package. In an example arrangement, the semiconductor dies can be mounted with a device side facing towards a surface of the hybrid isolation laminate using conductive post connects in a flip chip package. In alternative arrangements, the semiconductor dies can be oriented “face up” with the device side of the semiconductor die facing away from the hybrid isolation laminate and wire bonds can form electrical connections between the semiconductor die and the package substrate. The microelectronic device package can have a package body formed by a thermoset epoxy resin in a molding process, or by using epoxy, plastics, or resins that are liquid at room temperature and are subsequently cured. The package body may provide a hermetic package for the packaged device. The package body may be formed in a mold using mold compound in an encapsulation process, however, a portion of the leads of the package substrate are not covered during encapsulation, these exposed lead portions provide the terminals for the microelectronic device package.

The term “package substrate” is used herein. A package substrate is a substrate arranged to receive a semiconductor die and in the illustrated examples, other components, and to support the semiconductor die in a completed semiconductor device package. Package substrates useful with the arrangements include conductive leadframes, molded interconnect substrates (MIS), partially etched leadframes, pre-molded leadframes (PMLFs), embedded trace substrates (ETS), and multilayer package substrates.

The term “hybrid isolation laminate” is used herein. A hybrid isolation laminate has a substrate with a dielectric core, at least two prepreg layers over opposing surfaces of the core, and in addition, one or more resin film dielectric layers over at least one of the prepreg layers. The dielectric core can include glass reinforced fiber material. Foils of conductor material can be disposed over opposing sides of the dielectric core; the foils are subsequently patterned to form layers of trace level conductors. Alternatively, conductors can be formed over the opposing sides of the dielectric core by photolithography. The prepreg layers are formed over the opposing patterned trace level conductors on opposing planar surfaces of the dielectric core. The prepreg layers can include additional trace level conductor layers that can form patterned conductors. Conductive prepreg vias extending through the dielectric of the prepreg layers can couple the trace level conductor layers at different trace levels. A resin film dielectric material can be formed over one side of the substrate over one of the prepreg layers, and additional conductor layers can be formed spaced by the dielectric material of the resin film dielectric material including the additional trace level conductors and resin film conductive via connections extending through the resin film dielectric material between the trace level conductor layers. In an example arrangement, one or more layers of Ajinomoto Build-up Film (ABF) which is commercially available from Ajinomoto Fine-Techno Co., Inc. of Tokyo, Japan can be used for the resin film dielectric material. In an example arrangement, a multilayer conductor level process is performed by plating a prepreg trace level conductor on the exterior surface of the prepreg material. The resin film deposition process begins by covering the prepreg trace level conductor with a layer of the resin film material. A cure is performed to harden the resin film material. The resin film is a thermoset or thermoplastic material that hardens to a solid dielectric film material during a cure process. If needed, grinding or thinning can be performed on the solid dielectric film material. Via openings can be formed by laser drilling to expose portions of the top surface of the prepreg trace level conductors on the surface of the prepreg that is exposed from the solid dielectric film material. The film via openings are filled with conductor material to form conductive film vias. Additional plating layers can be formed to add additional levels of trace level conductors on the surface of the solid dielectric film material. By using the resin film dielectric material over the cored substrate, a hybrid isolation laminate is formed with the additive build-up dielectric film over at least one side of the cored substrate. The resin film has a dielectric constant that is greater than the dielectric constant for a similar thickness prepreg material, so that adding the resin film material provides a higher dielectric value for the hybrid isolation laminate. The hybrid isolation laminate advantageously provides a higher dielectric constant of the resin film dielectric material combined with the strength of the cored substrate material, providing both the robust electrical isolation resulting from use of the additive build-up material and providing the strength and reliability of the cored substrate. In an example arrangement, passive components including coils and transformers can be formed in the various conductor layers of the hybrid isolation laminate. An isolation barrier can be formed between the conductor layers and between semiconductor dies mounted to the hybrid isolation laminate to enable a system in the microelectronic device packages of the arrangements including an isolation barrier.

In an example arrangement, copper, gold, or tungsten conductors are formed by plating, and a thermoset material is used as the dielectric material. The conductive vias between trace level conductor layers can be formed by laser drilling or mechanical drilling to form via openings, and by filling the via openings with conductor material by using conductive plugs or plating to complete the conductive vias. Multiple levels of trace level conductors and conductive vias can be patterned as stacked conductors extending through the dielectric material, and these stacked conductors can form vertical rails or networks of connected traces. The cored substrate can also include through-vias, which are conductive vias in openings extending through the dielectric core to couple trace level conductors on either side of the dielectric core.

In packaging microelectronic and semiconductor devices, mold compound may be used to partially cover a package substrate, to cover the hybrid isolation laminate, to cover passive components, to cover semiconductor dies, and to cover the electrical connections made to the package substrate. This molding process can be referred to as an “encapsulation” process, although some portions of the package substrates are not covered in the mold compound during encapsulation, for example terminals can be formed by portions of conductive leads that are exposed from the mold compound to enable electrical connections to the microelectronic device package. Encapsulation is often a compressive molding process, where a thermoset mold compound such as an epoxy resin can be used. A room temperature solid or powdered epoxy resin mold compound can be heated to a liquid state, and then molding can be performed by pressing the liquid mold compound into a mold through runners or channels. Transfer molding can be used. Unit molds shaped to surround an individual device may be used, or a block molding process may be used, to form multiple packages simultaneously for several devices from mold compound. The devices to be molded can be provided in an array or matrix of several, hundreds or even thousands of devices in rows and columns that are then molded contemporaneously.

After the molding process is complete, the individual microelectronic device packages are cut apart from each other in a sawing operation. A mechanical saw is used to cut through the mold compound and package substrate material in saw streets formed between the devices. Portions of the package substrate leads that are exposed from the mold compound package to form terminals for the microelectronic device packages. In the example arrangements, a leadframe is used as a package substrate. In alternative arrangements, a molded interconnect substrate (MIS) or premolded leadframe (PMLF) can be used as the package substrate.

The term “scribe lane” is used herein. A scribe lane is a portion of semiconductor wafer between semiconductor dies. Sometimes in related literature the term “scribe street” is used. Once semiconductor processing is finished and the semiconductor devices are complete, the semiconductor devices are separated into individual semiconductor dies by severing the semiconductor wafer along the scribe lanes. The separated dies can then be removed and handled individually for further processing. This process of removing dies from a wafer is referred to as “singulation” or sometimes referred to as “dicing.” Scribe lanes are arranged on four sides of semiconductor dies and when the dies are singulated from one another, rectangular semiconductor dies are formed.

The term “saw street” is used herein. A saw street is an area between molded electronic devices used to allow a saw, such as a mechanical blade, laser, or other cutting tool to pass between the molded electronic devices to separate the devices from one another. This process is another form of singulation. When the molded electronic devices are provided in a strip with one device adjacent to another device along the strip, the saw streets are parallel and normal to the length of the strip. When the molded electronic devices are provided in an array of devices in rows and columns, the saw streets include two groups of parallel saw streets, the two groups are normal to each other, and the saw will traverse the molded electronic devices in two different directions to cut apart the packaged electronic devices from one another in the array.

The terms “trace level conductor layer,” “core trace level conductor layer,” and “prepreg trace level conductor layer” are used herein. A “trace level conductor layer” is a layer of conductive material that is patterned to form traces, and which provides routing for elements in the arrangements. The trace level conductor layers are formed over dielectric materials, and as labeled herein, the labels refer to the dielectric layer where the trace level conductor layers are formed. A “core trace level conductor layer” is a trace level conductor layer formed over a dielectric core, which is used to form a substrate in the arrangements. There can be a core trace level conductor layer on an upper, and on a lower, surface of the dielectric core, which is planar. A “prepreg trace level conductor layer” is a trace level conductor layer formed over a prepreg dielectric layer. In the arrangements, there can be a prepreg dielectric layer over both surfaces of the planar core, and thus there can be two prepreg trace level conductor layers. An additional trace level conductor layer can be formed over a resin film dielectric layer that is deposited over a prepreg layer.

In this description, the terms “conductive via,” “conductive through-via,” “core through-via,” “conductive prepreg via” and “conductive film via” are used. A conductive via, as used herein, is a conductor that extends in an opening through a dielectric layer. Conductive vias can be used in the arrangements to make vertical connections between trace level conductors that are spaced by dielectric material. A conductive through-via is made by forming conductor material in a hole extending through the dielectric core. A conductive prepreg via is made by forming an opening in a prepreg layer, for example by laser drilling, and filling it with a conductor material. A conductive film via is made by forming an opening in a resin film layer, for example by laser drilling, and filling it with a conductor material. The conductive vias form vertical electrical connections between the layers of trace level conductors and enables circuits to be formed in the hybrid isolation laminate of the arrangements.

In the arrangements, semiconductor dies, for example semiconductor dies arranged as drivers or receivers for coils or transformers, can be integrated with passive components, such as coils, to form an integrated system device in a microelectronic device package with an isolation barrier. The semiconductor dies can be coupled to the passive components by a portion of trace level conductors formed in the hybrid isolation laminate. In an example arrangement, a pair of semiconductor dies, electrically isolated from one another, are coupled to a primary coil and a secondary coil formed within the hybrid isolation laminate that are also electrically isolated from one another, but which are arranged to inductively couple. The primary coil and the secondary coil can be formed by patterning the conductors within the hybrid isolation laminate, for example planar coils can be formed that are spaced from one another by the dielectric material of the hybrid isolation laminate. Current can be delivered from the primary coil to the secondary coil by inductive coupling of the coils, that is, the hybrid isolation laminate includes a transformer. In additional example arrangements multiple passive components can be used.

Use of the hybrid isolation laminate in the arrangements enables the integration of the passive components and the semiconductor dies in a microelectronic device package with an isolation barrier. The microelectronic device package of the arrangements is relatively simple to assemble in packaging processes using known tools and known materials, and with increased reliability and performance over prior approaches. The use of the hybrid isolation laminate in the arrangements accrues benefits from the increased dielectric constant of the resin film dielectric material (over the dielectric constants provided by other substrate materials of similar thickness) and accrues further benefits from the rigidity and robustness of the cored substrate. By combining these technologies, reduced manufacturing tolerances allowing for thinner isolation substrates and accordingly, smaller microelectronics device packages with the needed electrical isolation are achieved and are manufacturable. In an example a critical isolation barrier thickness has a tolerance is reduced to about +/−7 microns, from a prior approach which had a critical thickness tolerance of greater than +/−15 microns. This reduced tolerance parameter results in more uniform substrate and isolation barrier thickness, and thus results in increased reliability and uniform performance between devices. In a further advantage, area limitations of a prior approach using only layers of the resin film to form an isolation barrier substrate are eased, so that the use of the hybrid isolation laminate in the arrangements allows a greater area, allowing for larger semiconductor dies and packages.

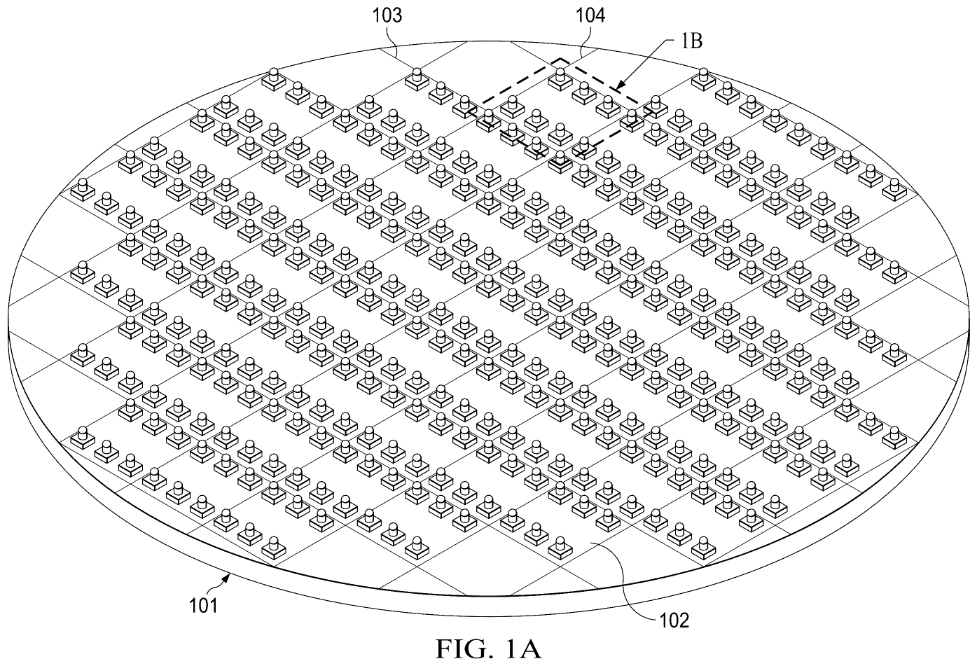

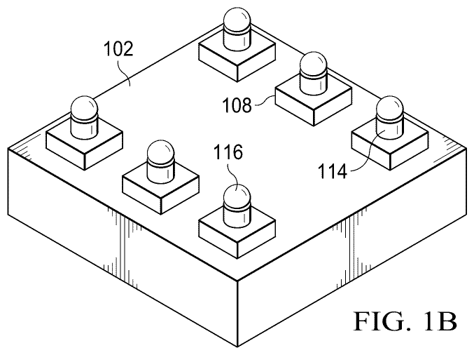

FIGS. 1A and 1B illustrate, in two projection views, a semiconductor wafer having semiconductor die devices formed on it that are configured for flip chip mounting, and an individual semiconductor die for flip-chip mounting, respectively. In FIG. 1A, a semiconductor wafer 101 is shown with an array of semiconductor dies 102 formed in rows and columns on a surface. The semiconductor dies 102 can be formed using processes in a semiconductor manufacturing facility, including ion implantation, doping, anneals, oxidation, dielectric and metal deposition, photolithography, pattern, etch, chemical mechanical polishing (CMP), electroplating, and other processes for making semiconductor devices. Scribe lanes 103 and 104, which are perpendicular to one another, and which run in parallel groups across the wafer 101, separate the rows and columns of the completed semiconductor dies 102, and provide areas for dicing the wafer 101 to separate the semiconductor dies 102 from one another.

FIG. 1B illustrates a single semiconductor die 102 taken from semiconductor wafer 101. Semiconductor die 102 includes bond pads 108, which are conductive pads that are electrically coupled to devices (not shown) formed in the semiconductor die 102. Conductive post connects 114 are shown extending away from a proximate end on the bond pads 108 on the surface of semiconductor die 102 to a distal end. The conductive post connects 114 can be formed by electroless plating or electroplating. In an example, the conductive post connects 114 are copper. In flip chip packages the conductive post connects may have solder bumps on the distal ends and are sometimes referred to as “copper pillar bumps.” Copper pillars can be formed by sputtering a seed layer over the surface of the semiconductor wafer 101, forming a photoresist layer over the seed layer, using photolithography to expose seed layer over the bond pads 108 in openings in the layer of photoresist, and plating the copper conductive post connects 114 on the bond pads. Other conductive materials can be used for the conductive post connects in an electroplating or electroless plating operation, including gold, silver, nickel, palladium, or tin, for example. Not shown for clarity of illustration are under-bump metallization (UBM) portions which can be formed over the bond pads to improve plating and adhesion between the conductive post connects 114 and the bond pads 108. After the plating operations, the photoresist is then stripped, and the excess seed layer is etched from the surface of the wafer. Polyimide (PI) (not shown) or other dielectric can be applied between the conductive post connects to protect the semiconductor die 102 and the conductive post connects 114. The semiconductor dies 102 are then separated by dicing, or are singulated, using the scribe lanes 103, 104 (see FIG. 1A).

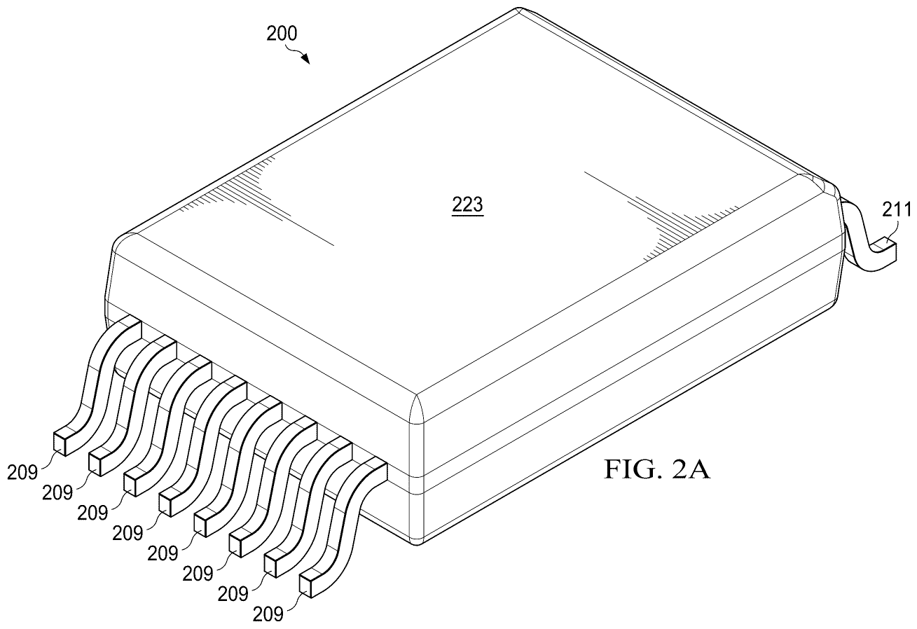

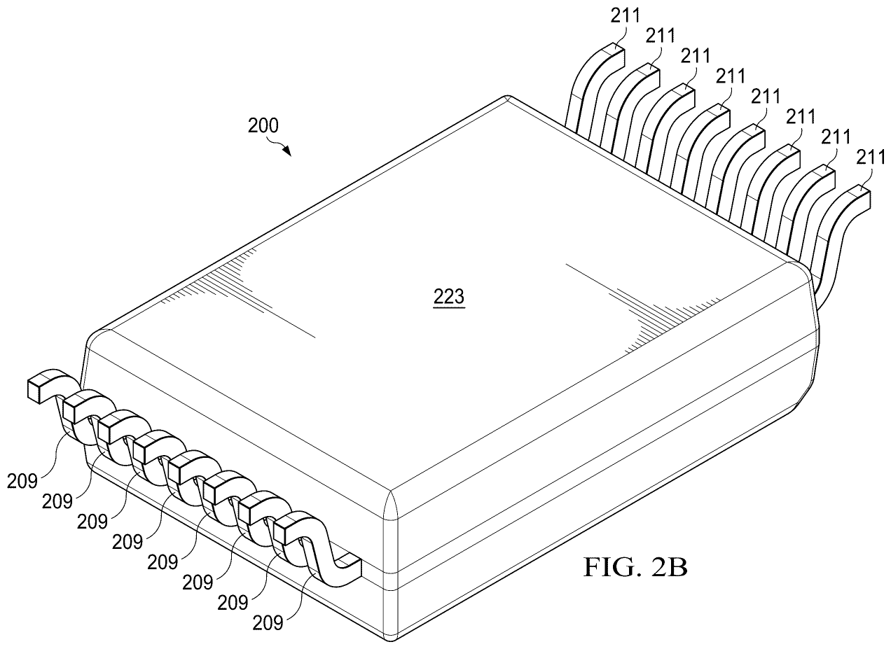

FIGS. 2A-2B illustrate, in projection views from a top view and a bottom view, respectively, a microelectronic device package 200 that can be used with an arrangement. In FIG. 2A, the microelectronic device package 200 is shown in a projection view from a top side surface. In the illustrated example, the microelectronic device package 200 is a small outline package (SOP). One type of small outline package useful with the arrangements is a small outline integrated circuit (SOIC) package. Another type of small outline package useful with the arrangements is a wide-SOIC package, which has a wider body. The body of the microelectronic device package 200 can be formed by mold compound 223. Leads 209 are shown extending from a middle portion of the mold compound 223, and in the illustrated example the leads are shaped in a “gull wing” shape for use in surface mounting to a system board, for example using processes for surface mounting technology (“SMT”).

In FIG. 2B, a projection view taken from the bottom surface of the microelectronic device package 200 is shown. Leads 211 are shown on the opposite side of the body formed by mold compound 223 from leads 209. In an example the leads 209 are a first set of conductive leads arranged to be coupled to a first voltage domain, while leads 211 are a second set of conductive leads arranged to be coupled to a second voltage domain that is isolated from the first voltage domain. The leads 211 and 209 extend away from the package body formed by mold compound 223 and are shaped to form “feet” at the outward ends for surface mounting. Other lead shapes can be used. An advantage of gull wing shaped leads is that these leads allow for some slight movement, for example due to movement of a board or of a device during package mounting, or due to thermal expansion while in operation, the slight movement of the leads can occur without causing a solder joint failure, thereby increasing board level reliability (“BLR”).

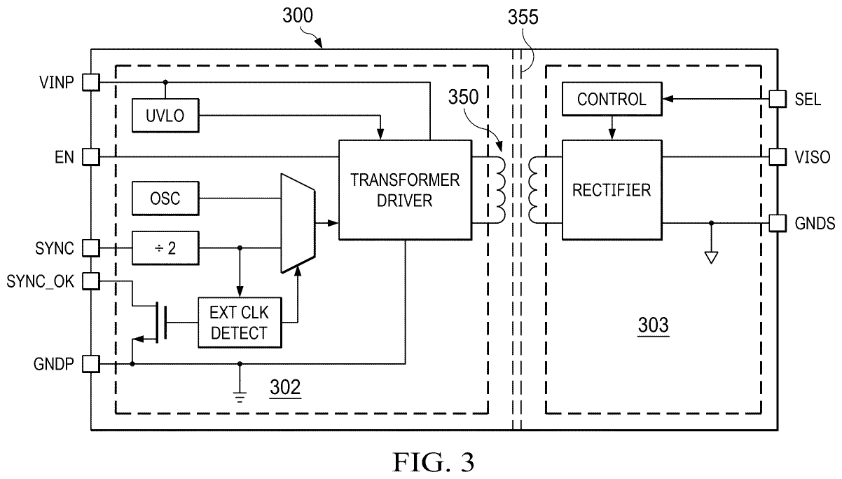

FIG. 3 illustrates, in a block diagram, a DC-DC converter circuit 300 which can be implemented in an example arrangement. In FIG. 3, a voltage input “VINP” and an associated ground “GNDP” are arranged to be coupled to an input voltage such as 5 Volts and an associated ground of a first voltage domain. A driver device 302, which can be implemented on a first semiconductor die, is shown with a circuit coupled to a primary coil on one side of a transformer 350. The driver device 302 includes, in this example circuit, the clocked transformer driver (labeled “TRANSFORMER DRIVER”) which can use pulse width modulation to supply energy to the primary coil of transformer 350. By driving transformer 350, the DC-DC converter 300 can supply a regulated output voltage on an isolated output voltage on the terminal labeled “VISO.” Other circuitry such as an under-voltage lockout circuit (labeled “UVLO”), an oscillator (labeled “OSC”), a frequency divider circuit (labeled “÷2”), an external clock detector (labeled “EXT CLK DETECT”), are included in the semiconductor device used to implement driver 302. The transformer 350 is coupled by a secondary coil to a receiver device 303 that can be implemented on a second semiconductor die, which as shown in FIG. 3 can include a rectifier circuit (labeled “RECTIFIER”) coupled to the secondary coil of the transformer 350, and a controller (labeled “CONTROL”) that selects the output voltage level for the output voltage VISO, which is provided relative to the ground GNDS, the output voltage terminal VISO and ground terminal GNDS being coupled to a second voltage domain. In operation, the DC-DC converter circuit 300 outputs an isolated output voltage VISO from the input voltage VINP. Isolation barrier 355 is formed within a microelectronics device package for circuit 300. In example arrangements, a DC-DC converter in a microelectronic device package using the hybrid isolation laminate of the arrangements can have an isolation voltage rating of up to 3 kVᵣₘₛ, with a surge capability of up to 6.5 kVₚₖ.

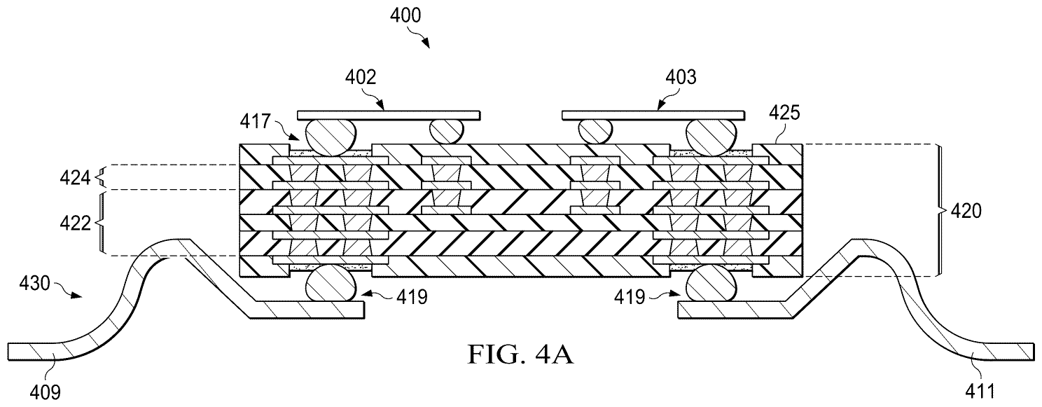

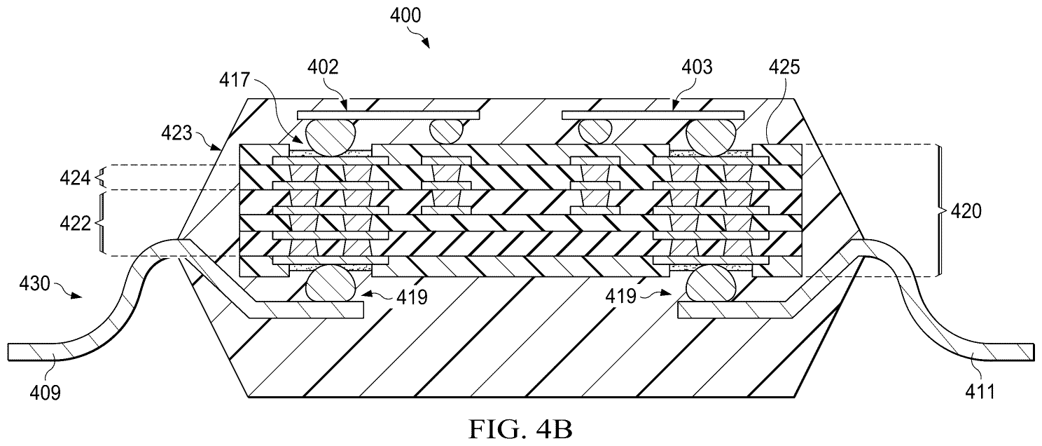

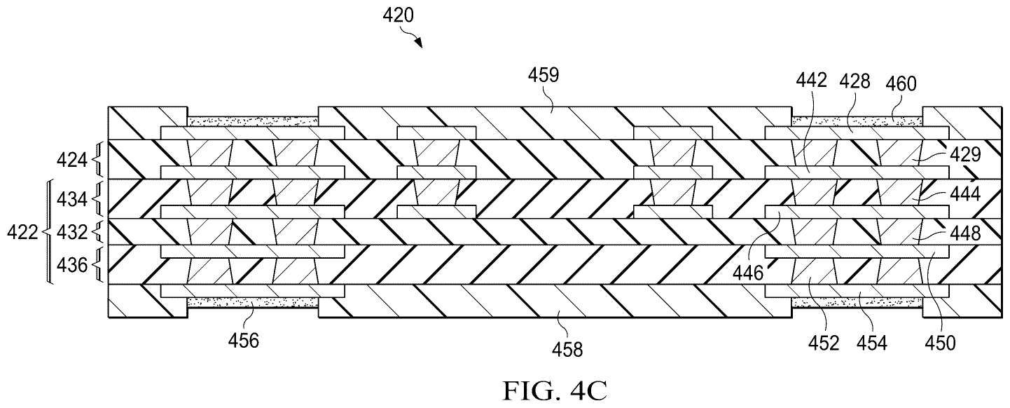

FIG. 4A illustrates, in a cross-sectional view, selected details of a microelectronics device package 400 of an example arrangement. In FIG. 4A, a hybrid isolation laminate 420 is shown with a cored substrate 422 and a resin film dielectric layer 424. A first semiconductor die 402 is shown flip-chip mounted to a device side surface 425 of the hybrid isolation laminate 420. A second semiconductor die 403 is shown flip-chip mounted to the device side surface 425 of the hybrid isolation laminate 420, the second semiconductor die 403 is spaced from the semiconductor die 402. Solder joints 417 are formed between conductors exposed on the device side surface 425 of the hybrid isolation laminate 420 and bond pads (not shown, see bond pads 108 in FIG. 1B for example) on the semiconductor dies 402, 403. The hybrid isolation laminate 420 is mounted to leads 409, 411 of a package substrate 430 by solder joints 419. The package substrate 430 has the first set of conductive leads 409 which are spaced from the second set of conductive leads 411. The leads 409 are arranged for coupling to a first voltage domain. Leads 411 are arranged for coupling to a second voltage domain. The hybrid isolation laminate 420 provides electrical isolation between the leads 409 arranged for the first voltage domain and the leads 411 arranged for the second voltage domain. Further, the hybrid isolation laminate provides electrical isolation between the semiconductor dies 402 and 403.

FIG. 4B illustrates the elements of FIG. 4A after encapsulation by a compressive molding process. In FIG. 4B, mold compound 423 is shown covering the hybrid isolation laminate 420, the semiconductor dies 402 and 403, and portions of the package substrate 430, to form a microelectronics device package 400 with isolation. In one example, the microelectronics device package 400 can include a DC-DC converter device, with circuitry similar to that shown for circuit 300 in the block diagram of FIG. 3. Other circuitry requiring an isolation barrier can be implemented using the hybrid isolation barrier 420 to form additional arrangements.

FIG. 4C illustrates, in a detailed cross-sectional view, additional details of the hybrid isolation laminate 420. (Note that the use of the relative terms “top” and “bottom” in this paragraph refer to the orientation of the hybrid isolation laminate 420 as oriented and shown in FIG. 4C.) In FIG. 4C, a cored substrate 422 includes a dielectric core 432, a prepreg layer 434, and another prepreg layer 436. A resin thermoset film layer 424 overlies the cored substrate 422. A trace level conductor layer 428 is shown at the top surface of the hybrid isolation laminate 420, overlying the dielectric of the resin thermoset film layer 424. A conductive film layer via 429 includes conductive vias that extend through the resin thermoset film layer 424. A prepreg trace level conductor layer 442 lies over the prepreg layer 434. A conductive prepreg via layer 444 includes conductive vias that extend through the prepreg layer 434. A core trace level conductor layer 446 lies over the top surface of the dielectric core 432. Conductive through-vias in a core through-via level 446 extend through the dielectric core 432. A bottom core trace level conductor layer 450 lies on the bottom surface of the dielectric core 432. A conductive prepreg via layer 452 includes conductive vias that extend through the prepreg layer 436. Another prepreg trace level conductor layer 454 lies over the bottom surface of the prepreg layer 436, on the bottom surface of the hybrid isolation laminate 420. A bottom solder resist layer 458 is shown over the bottom surface of the hybrid isolation laminate 420 with openings to expose the prepreg trace level conductor layer 454 in selected positions. When copper or copper alloy is used to form the trace level conductors, an organic solderability preservative (OSP) 456 layer can be deposited over the exposed portions of the trace level conductor layers to prevent copper ion diffusion, reduce tarnish and prevent oxidation of the copper, to increase the solderability of the exposed copper trace level conductors in subsequent processes.

In FIG. 4C, OSP layer 456 is shown deposited over exposed trace level conductors. In addition, protective platings (not shown for clarity of illustration) such as gold, nickel, palladium, silver or protective combination layer plating such as “ENIG” (electroless nickel, immersion gold) and “ENEPIG” (electroless nickel, electroless palladium, immersion gold) can be formed over the exposed copper trace level conductor surfaces to prevent ion diffusion and degradation of the copper surfaces. A top solder resist layer 459 is shown overlying the first trace level conductor layer 428. Again, an OSP layer 460 can be applied to exposed portion of the first trace level conductor layer 428.

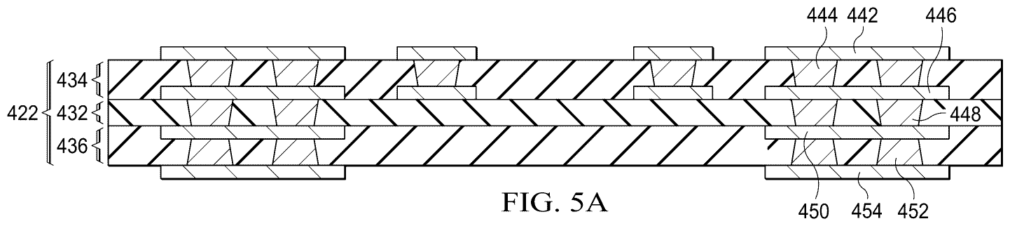

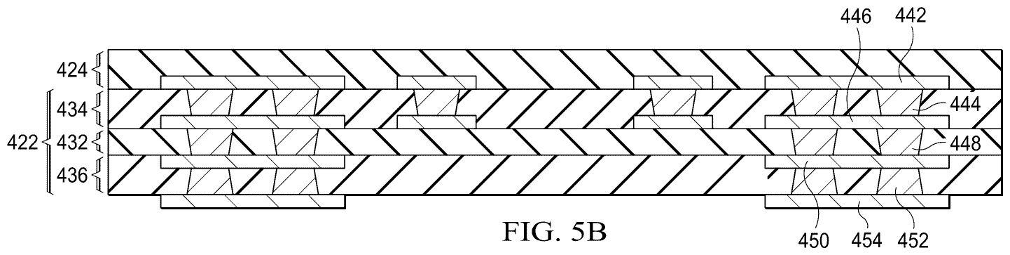

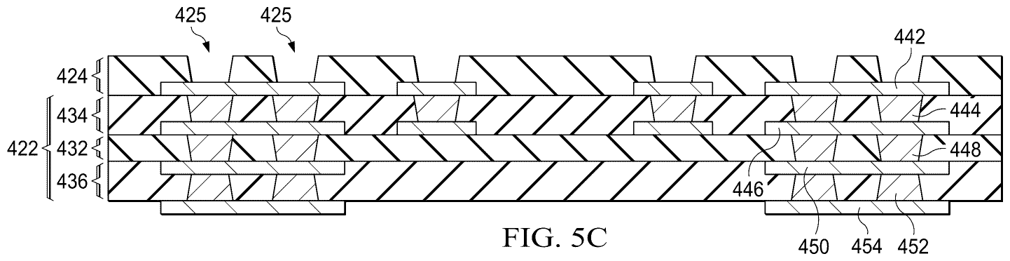

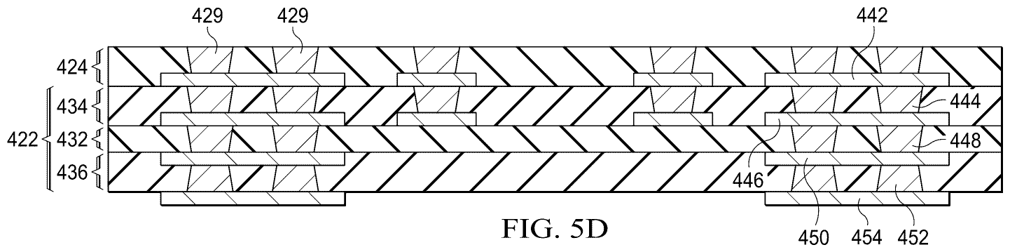

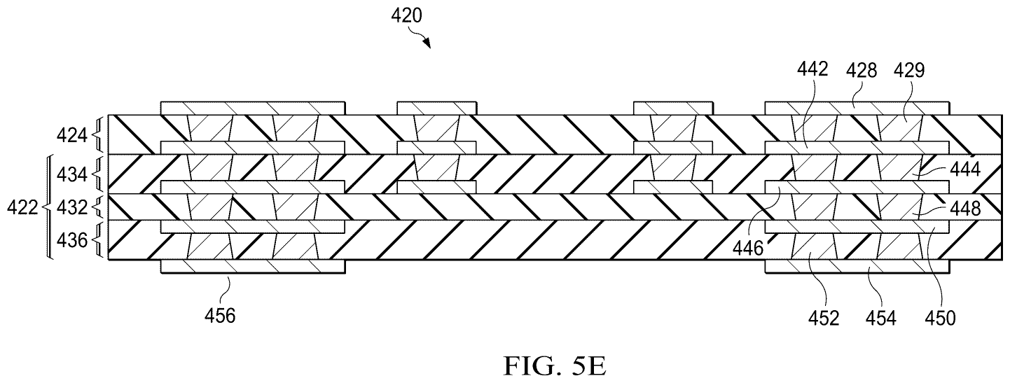

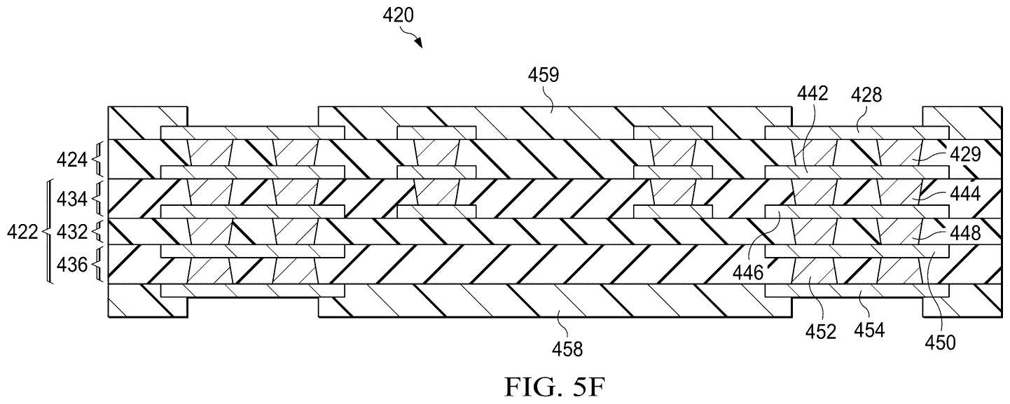

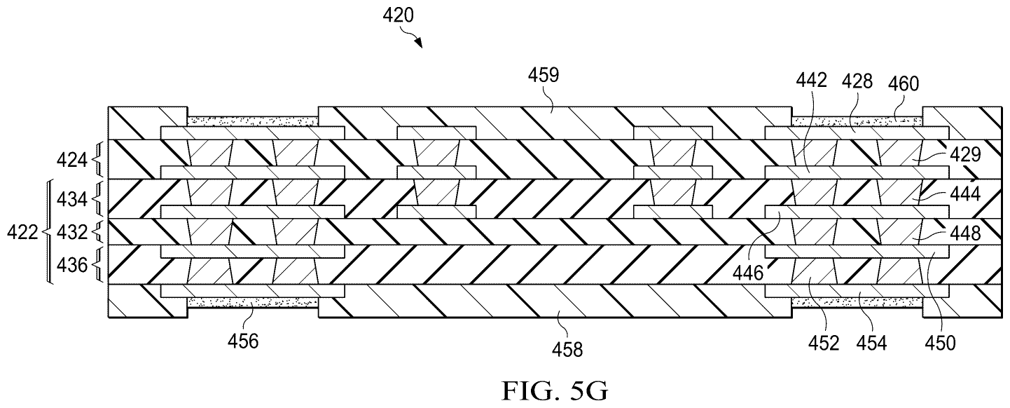

FIGS. 5A-5G illustrate, in a series of cross-sectional views, selected steps for forming the hybrid isolation laminate 420 shown in FIG. 4C.

In FIG. 5A, the cored substrate 422 is shown in a cross-sectional view. Cored substrate 422 includes the dielectric core 432, a top prepreg layer 434, and a bottom prepreg layer 436. A core trace level conductor layer 446 is shown over the upper surface of the dielectric core 432. A bottom core trace level conductor layer 450 is shown over the bottom surface of the dielectric core 432. Through-vias 448 can be formed by forming openings through the dielectric core 432 and filling the openings with conductor material to form the conductive though-vias 448 between the core trace level conductor layer 446 and the core trace level conductor layer 450.

A top prepreg layer 434 is shown formed over the top surface of the dielectric core 432. The top prepreg layer 434 is formed over the core trace level conductor layer 446. A bottom prepreg layer 436 is shown formed over the bottom surface of the dielectric core 432. The bottom prepreg layer 436 and the top prepreg layer 434 are formed using glass cloth layers that are impregnated with resin and which are partially cured. The prepreg layers 434, 436 can be completed by via formation, prepreg trace level conductor formation, and additional curing to harden the prepreg layers to complete the cored substrate 422.

The top prepreg layer 434 includes conductive prepreg vias 444 and prepreg trace level conductor layer 442 is formed over the prepreg layer 434. The conductive prepreg vias 444 can be formed by using a laser drill to form openings in the prepreg layer 434 and exposing the core trace level conductor 446, and the openings can then be filled with conductor material to form the conductive prepreg vias using plating or by use of conductive plugs. The prepreg trace level conductor layer 442 is formed over the top surface of the prepreg layer 434 and can be patterned using photolithography and etch to pattern the prepreg trace level conductor layer 442.

Similar processes are used to form the conductive prepreg vias 452 between the bottom core trace level conductor layer 448 and a prepreg trace level conductor layer 454. The cored substrate 422 thus includes the core top trace level conductor layer 446, the top prepreg trace level conductor layer 442, the bottom core trace level conductor 450, and the prepreg trace level conductor layer 454, coupled in portions by vias in conductive prepreg via layer 444, core through-vias in layer 448, and conductive prepreg vias in layer 452. Passive components such as planar coils can be formed in the trace level conductors of the cored substrate 422 and coupled using the various via layers. In an example arrangement, a first planar coil is formed in a trace level conductor layer on one side of the dielectric core 432, and a second planar coil is formed in a trace level conductor layer on the opposite side of the dielectric core 432, the first planar coil and the second planar coil are electrically isolated from one another, and are arranged to inductively couple to one another to form a transformer.

FIG. 5B illustrates, in another cross-sectional view, the elements of FIG. 5A after additional processing. A resin film dielectric layer 424 formed by a film deposition process is formed over the top surface of the cored substrate 422, over the prepreg trace level conductor layer 442. In an example process, Ajinomoto Build-Up Film (ABF), is used to form the resin film dielectric layer 424. ABF is a thermoset resin film that can be stretched and positioned over the cored substrate 422 and then heated to allow the film to soften and conform to the underlying structures. A vacuum can be used to cause the ABF film to cover the underlying structures conformally without voids, and the resin film is cured to harden and form a solid dielectric film layer 424.

FIG. 5C illustrates in a further cross-sectional view, the elements of FIG. 5B after further processing. In FIG. 5C, openings 425 are formed in a drilling operation, for example using a laser drill, to begin film via formation through the solid dielectric film layer 424. Openings 425 are located to expose the top surface of the underlying prepreg trace level conductor layer 442.

FIG. 5D illustrates, in a further cross-sectional view, the elements shown in FIG. 5C, after film layer conductive vias 429 are completed by depositing conductor material in the via openings (see openings 425 in FIG. 5C). The film layer conductive vias 429 extend through the solid dielectric film layer 424 to the prepreg trace level conductor layer 442 on the top surface of the cored substrate 422.

FIG. 5E illustrates, in another cross-sectional view, the elements shown in FIG. 5D after an additional process step. In FIG. 5E, an additional trace level conductor layer 428 is shown formed over the solid dielectric film layer 424 and contacting the film layer conductive vias 429. In an example arrangement, the additional trace level conductor layer 428 is used to form conductive lands for mounting semiconductor dies, for example using flip chip mounting. A hybrid isolation laminate 420 is now formed including the solid dielectric film layer 424 and the cored substrate 422.

FIG. 5F illustrates, in an additional cross-sectional view, the elements of FIG. 5E after solder resist is applied. A layer of solder resist 459 is applied to the upper surface of the hybrid isolation laminate 420, and a similar layer of solder resist 458 is applied to the lower surface of the hybrid isolation laminate 420, to protect the surfaces from unwanted solder during subsequent processing.

FIG. 5G illustrates the hybrid isolation laminate 420 of FIG. 5F after an additional processing step. In FIG. 5G, the exposed portions of the additional trace level conductor layer 428 and the trace level conductors 454 are covered by an optional layer of OSP (organic solderability preservative) 460 and 456 to prevent tarnish and oxidation of the trace level conductor material, which can be copper, gold, or alloys of these.

The hybrid isolation laminate 420 includes the cored substrate 422, with a dielectric core 432, and two prepreg layers 434, 436, on the opposite of either side of the core. The hybrid isolation laminate 420 also includes the resin thermoset film layer 424, which can be an ABF film. By combining these materials in a hybrid isolation laminate, the advantages of the resin thermoset film, including the dielectric constant of the resin film, and the close tolerances, rigidity and strength of the cored substrate are used together to provide a robust and reliable hybrid isolation laminate for use in a microelectronic device package with an isolation barrier, at lower cost than a routable lead frame or other film based multilayer substrate used in prior approaches. The reduced tolerance parameter achieved by use of the hybrid isolation laminate results in more uniform isolation barrier thickness, and therefore better reliability.

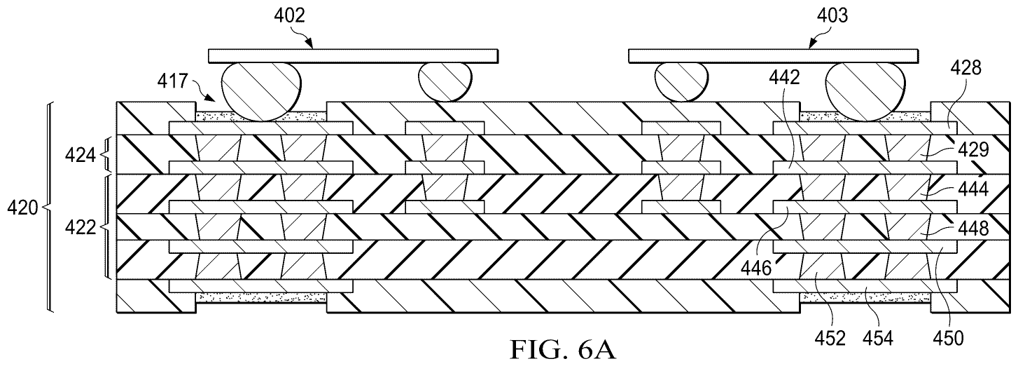

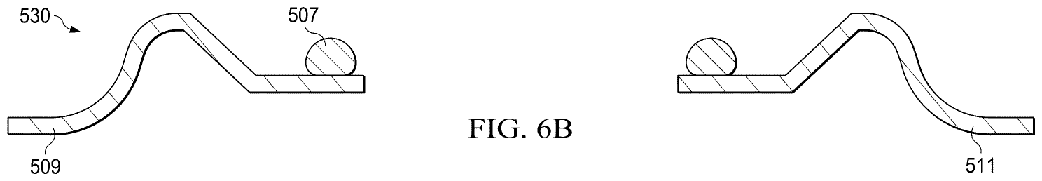

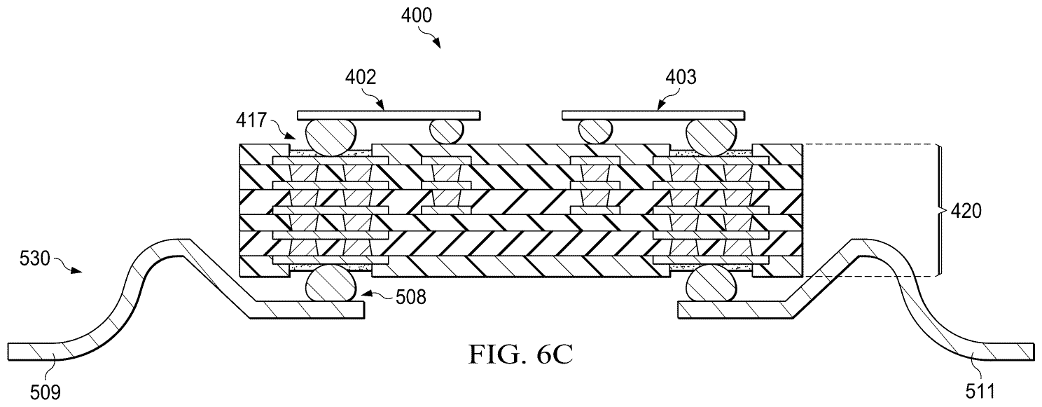

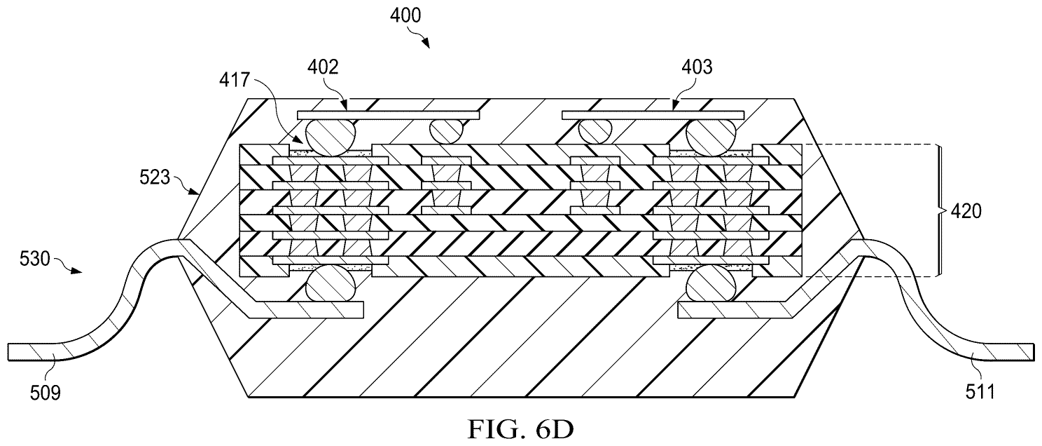

FIGS. 6A-6D illustrate, in a series of cross-sectional views, steps for assembly of a microelectronic device package of an arrangement including the example hybrid isolation laminate 420 of FIG. 5G.

In FIG. 6A, semiconductor dies 402 and 403 are shown flip chip mounted to the hybrid isolation laminate 420 (on the top side of hybrid isolation laminate 420 as the elements are oriented in FIG. 6). The flip chip mount for the semiconductor dies 402, 403 uses solder balls on the bond pads of the semiconductor dies in a thermal reflow process to form solder joints 417 that mechanically attach and electrically couple the semiconductor dies 402 and 403 to the hybrid isolation laminate 420.

FIG. 6B illustrates, in another cross-section, a package substrate 530 arranged to receive the hybrid isolation laminate 420. In FIG. 6B, the conductive leads 509, 511 are shown spaced from one another in two sets of conductive leads to provide a first set of leads 509 arranged to couple to a first voltage domain, for example an input voltage and the associated ground, and a second set of leads 511 arranged to couple to a second voltage domain, for example an output voltage and the associated ground. The package substrate 530 can be one unit of a strip, array, or grid (not shown for clarity of illustration), which can be tens or hundreds of units provided in a strip, grid, or array for simultaneous processing in a packaging assembly process, to increase throughput and lower device costs. The package substrate 530 is shown in a downset lead arrangement, with the internal ends of the leads 509, 511 displaced towards the bottom of the molded package, so that additional space on the device side of the leads 509, 511 is created to allow for the thickness of semiconductor dies and the hybrid isolation laminate without the need to increase the thickness of the overall package, as will be clear from the description below and as shown in FIGS. 6C-6D. In alternative arrangements, other leadframe types such as an upset leadframe with devices mounted on the board side can be used. Solder balls 507 are shown deposited on the internal ends of leads 509 and the internal ends of leads 511 in preparation for mounting the hybrid isolation laminate to the package substrate 530.

FIG. 6C illustrates, in another cross-sectional view, the package substrate 530, in the illustrated example a leadframe, and the hybrid isolation laminate 420, after a mounting step. The hybrid isolation laminate 420 is mounted on the internal ends of the first set of leads 509 and the second set of leads 511 by using the solder balls (see 507 in FIG. 6B) to form solder joints 508 in a thermal reflow process. By selecting the solder used in solder balls 507 to reflow at a lower temperature than the solder balls used to flip chip mount the semiconductor dies 402, 403, the second thermal reflow process to form solder joints 508 can be performed without disturbing the solder joints 417 formed on the top surface of the hybrid isolation laminate 420. The solder joints 508 are formed between conductive lands formed by exposing portions of the trace level conductor layer on the bottom of the hybrid isolation laminate 420 from the solder resist at the bottom surface of the hybrid isolation laminate 420. By patterning the trace level conductors and by use of the various conductive vias in the hybrid isolation laminate the first set of leads 509 can be coupled to the first semiconductor die 402, while the second set of leads 511 can be coupled to the second semiconductor die 403, the first set of leads 509 and the second set of leads 511 being isolated from one another.

FIG. 6D illustrates, in a further cross-sectional view, the elements shown in FIG. 6C after a molding process forms the microelectronic device package 400. In FIG. 6D, a package body is formed using a mold compound 523. In an example process useful with the arrangements, epoxy resin mold compound can be used in a transfer mold. Solid pucks or powdered resin epoxy mold compound can be placed in a mold tool and heated to a liquid state. The resin epoxy mold compound is a thermoset material. Once the resin epoxy mold compound is in a liquid state, hydraulic pressure can be used to force the liquid mold compound into runners to fill a mold chase and to surround the semiconductor dies 402, 403, the hybrid isolation laminate 420, and portions of the package substrate 430 with mold compound. The mold compound is cured and forms a solid body for the microelectronic device package. Portions of the first set of leads 509 and the second set of leads 511 are left exposed from and extending from the package body formed by the mold compound 523, and the exposed portions form terminals for the microelectronic device package 400. In the example arrangement of FIG. 6D, an SOIC type package is shown. Other package types can be used with the arrangements such as SOP (small outline package) and wide-SOIC type packages. The arrangements can be used with leadless microelectronic device packages such as quad flat no-lead packages. Dual in-line packages (DIPs) can be used. In the illustrated arrangement, the SOIC microelectronic device package 400 provides a distance between the first set of leads 509 and the second set of leads 511, which are arranged to be coupled to isolated voltage domains, that is sufficient to meet minimum creepage distance requirements, the distance between leads of different potentials over the package body, and minimum clearance distance requirements, the distance between leads of different potentials in air, to prevent unwanted leakage.

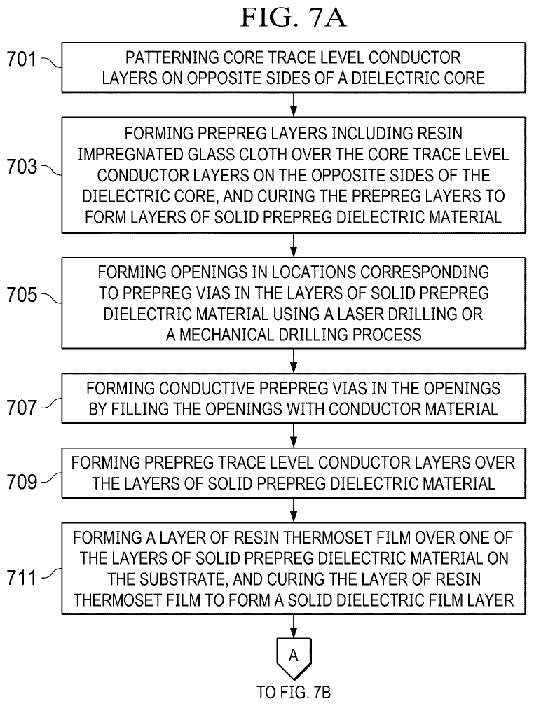

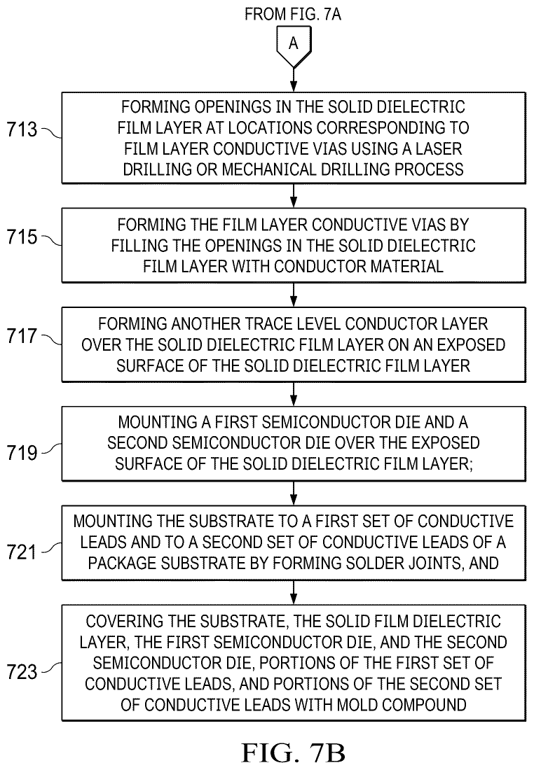

FIGS. 7A-7B illustrate, in flow diagrams, the steps used to form a hybrid isolation laminate for use with the arrangements, and additional steps used to form a microelectronic device package using the hybrid isolation laminate in an example arrangement.

In FIG. 7A, the method begins at step 701, where core trace level conductors are formed by patterning on opposite sides of a dielectric core. (See, for example, FIG. 5A. where core 432 is shown with a top core trace level conductor layer 446 and a bottom core trace level conductor layer 448 on opposite sides of the core 432 of dielectric material. The core 432 shown in FIG. 5A can be formed of cured glass reinforced cloth, such as flame retardant 4 (“FR4”), of bismaleimide-triazine (“BT”) resin, of semiconductor material, or of other dielectric material. The core trace level conductor layers (see 446, 448 in FIG. 5A) can be formed from conductor foil layers laminated to the core, or from conductor layers that are formed using electroplating or electroless plating and can be formed of copper, gold, or aluminum as examples. Typically, copper is used. The core trace level conductor layers 444, 448 can be patterned using photolithography and etch processes. When the dielectric core 432 is positioned horizontally as shown in FIG. 5A for example, the core trace level conductor layers form horizontal conductor layers that can be coupled through the dielectric core 432 by through-vias (see for example through-vias 448 in FIG. 5A) that can be formed prior to the conductors in a “via first” process by mechanical or laser drilling openings in the dielectric core 432 at via locations, and then forming conductive vias in the openings. Alternatively, a “via last” process can form the conductive through-vias after the core trace level conductors are formed, again by laser or mechanical drilling processes at via location and adding conductor materials to form the conductive through-vias.

At step 703, the method continues by forming prepreg layers including resin impregnated glass cloth over the core trace level conductor layers on the opposite sides of the dielectric core and curing the prepreg layers to form layers of solid prepreg dielectric material. (See, for example, layers 434, 436 in FIG. 5A.) At step 705, the method continues by forming openings in location corresponding to prepreg vias in the layers of solid prepreg dielectric material on the opposite sides of the dielectric core using a laser drilling or mechanical drilling process. At step 707, the method continues by forming conductive prepreg vias in the openings by filling the opening with conductor material. (See, for example, FIG. 5A, where vias 444 are shown in the prepreg layer 434, and vias 452 are formed in layer 436.)

At step 709, the method continues by forming prepreg trace level conductor layers over the layers of solid prepreg dielectric material. (See, for example, FIG. 5A where prepreg trace level conductor layer 442 is formed over the solid prepreg dielectric material in prepreg layer 434, and prepreg trace level conductor layer 454 is formed over the solid dielectric material of prepreg layer 436.)

Steps 701-709 form a multilayer package substrate with a dielectric core and prepreg layers formed on opposite sides of the dielectric core, and trace level conductor layers formed over the opposite sides of the dielectric core and over the prepreg layers which can be coupled using vias to form connections between the trace level conductor layers, (see the substrate 422 in FIG. 5A.)

At step 711, the method continues by forming a layer of resin thermoset film over one of the layers of solid prepreg dielectric material on the substrate and curing the layer of resin thermoset film to form a solid dielectric film layer. See, for example, the layer of resin thermoset film 424 in FIG. 5B, which in an example process is Ajinomoto Build-up Film (ABF). In an example process, the resin thermoset film is heated to soften the film and positioned over the layer of solid prepreg dielectric material, and a vacuum is applied to cause the layer of resin thermoset film to conform to the structures underlying the film. A curing cycle in an oven then cures the resin thermoset film to a solid dielectric film layer.

The method continues at step 713 in FIG. 7B by forming openings in the solid dielectric film layer at locations corresponding to film layer conductive vias using a laser drilling or mechanical drilling process. (See, for example the via openings 425 shown in FIG. 5C). This example process is a “via first” process, in an alternative approach that can also be used, the process of via formation can be performed after trace level conductors are formed, in a “via last” process, that is steps 713 and 715 of FIG. 7B could be performed after step 717, instead of the sequence shown in the example of FIG. 7B. Step 715 continues the via formation process by forming film layer conductive vias in the openings by filling the openings with conductor material. (See, for example conductive film vias 429 in FIG. 5D, which are shown after the via openings 425 (see 425 in FIG. 5C) are filled with conductor material, such as copper, gold, titanium, tungsten, or alloys of these. Plugs or electroplating can be used to form the filled vias.)

At step 717 another trace level conductor layer is formed over the solid dielectric film layer. (See, for example, the trace level conductor layer 528 in FIG. 5E.) The steps of FIGS. 7A-7B, from 701 to 717, form the hybrid isolation laminate 420 shown in FIG. 5E, for example. The hybrid isolation laminate of the arrangements advantageously includes the substrate 422 of FIG. 5E, with the rigidity of a cored substrate, and with the manufacturability of the cored substrate, but also includes the dielectric properties of the film dielectric layer 426, which is formed from resin thermoset film. By incorporating the resin thermoset film with the cored substrate, the hybrid isolation laminate can provide an isolation barrier in a laminate that has the dielectric constant of the resin thermoset film with the rigidity and strength of the cored substrate.

The method continues to step 719 of FIG. 7B. In step 719, a first semiconductor die and a second semiconductor die are mounted over the exposed surface of the solid dielectric film layer. (See FIG. 6A, where semiconductor dies 402 and 403 are shown mounted to the hybrid isolation laminate 420.) In the illustrated example of FIG. 6A, the semiconductor dies are flip chip mounted with device surfaces facing the hybrid isolation laminate, and solder joints formed between the semiconductor dies and the exposed surfaces on the solid dielectric film layer 424. In an alternative approach that can be used, a face up mounting with wire bond connections from the semiconductor dies 402, 403 to the hybrid isolation laminate 420 can be used to form additional alternative arrangements.

The method then continues to step 721, where the substrate is mounted to a first set of conductive leads and to a second set of conductive leads of a package substrate by forming solder joints. (See, for example, FIG. 6B, where solder balls are shown deposited on the inner ends of the first set of leads and the second set of leads 509, 511, of package substrate 530, which is a leadframe in the illustrated example. In FIG. 6C, the hybrid isolation laminate 420 is shown mounted to the first set of leads 509 and the second set of leads 511 by solder joints 508 formed from the solder balls. The first set of leads 509 and the second set of leads 511 are arranged to be coupled to isolated voltage domains.) In an example application, a DC-DC converter has a first set of terminals for coupling to an input voltage, and a second set of terminals for coupling to an output voltage, the input voltage and the output voltage having isolated grounds. Coils formed within the hybrid isolation laminate 420 are coupled to the first set of leads 509 or the second set of leads 511 and are electrically isolated, while being inductively coupled. The hybrid isolation laminate 420 of the arrangements provides an isolation barrier, while energy can be transferred across the isolation barrier,

The method continues at step 723, where the substrate, the solid dielectric film layer, the first semiconductor die, the second semiconductor die, and portions of the first set of leads and of the second set of leads are covered by mold compound in a transfer molding process. Portions of the first set of leads and the second set of leads that extend from the mold compound form terminals for a microelectronic device package. (See, for example, the microelectronic device package 400 of FIG. 6D.)

The use of the hybrid isolation laminate of the arrangements and methods for forming a microelectronic device package of the arrangements provides microelectronic device packages including semiconductor dies with integral passive components that are isolated from one another by an isolation barrier to provide high isolation voltages. Existing materials and assembly tools are used to form the arrangements, and the arrangements are relatively low in cost. The use of the arrangements allows microelectronic device packages including isolation barriers with simplified packaging processes and increased reliability (when compared to similar microelectronic device packages formed without use of the arrangements.)

Modifications are possible in the described arrangements, and other alternative arrangements are possible within the scope of the claims.

What is claimed is:

1. A method, comprising:
forming a substrate by:
patterning core trace level conductor layers on opposite sides of a dielectric core;
depositing prepreg layers comprising resin impregnated glass cloth over the core trace level conductor layers on the opposite sides of the dielectric core, and curing the prepreg layers to form layers of solid prepreg dielectric material;
forming openings in locations corresponding to prepreg vias in the layers of solid prepreg dielectric material using a laser drilling or a mechanical drilling process;
forming conductive prepreg vias in the openings by filling the openings with conductor material; and
forming prepreg trace level conductor layers over the layers of solid prepreg dielectric material;
forming a layer of resin thermoset film over one of the layers of solid prepreg dielectric material on the substrate, and curing the layer of resin thermoset film to form a solid dielectric film layer;
forming openings in the solid dielectric film layer at locations corresponding to film layer conductive vias using a laser drilling or mechanical drilling process;
forming film layer conductive vias by filling the openings in the solid dielectric film layer with conductor material; and
forming another trace level conductor layer over the solid dielectric film layer.

2. The method of claim 1, wherein the solid dielectric film layer has a first dielectric constant that is greater than a second dielectric constant of the substrate.

3. The method of claim 1, and further comprising forming a first planar coil and a second planar coil using ones of the core trace level conductor layers, the prepreg trace level conductor layers, and the another trace level conductor layer.

4. The method of claim 3, wherein the first planar coil and the second planar coil are electrically isolated from one another by dielectric materials of the substrate.

5. The method of claim 4, wherein the first planar coil and the second planar coil are formed on opposite sides of the dielectric core of the substrate.

6. The method of claim 5, and further comprising arranging the first planar coil and the second planar coil to inductively couple to one another while remaining electrically insulated from one another.

7. The method of claim 6, and further comprising forming a transformer using the first planar coil and the second planar coil.

8. The method of claim 1, wherein forming the layer of resin thermoset film over one of the layers of solid prepreg dielectric material further comprises forming a layer of Ajinomoto Build-Up Film.

9. A method for forming a microelectronics device package, comprising:
forming a substrate by: patterning core trace level conductor layers on opposite sides of a planar dielectric core, forming prepreg layers of resin impregnated glass cloth over the core trace level conductor layers on the opposite sides of the planar dielectric core, curing the prepreg layers to form layers of solid dielectric prepreg material, forming openings in locations corresponding to prepreg vias in the layers of solid dielectric prepreg material using a laser drilling or mechanical drilling process, forming conductive prepreg vias by filling the openings with conductor material, and forming prepreg trace level conductors over the layers of solid dielectric prepreg material on opposite sides of the planar dielectric core;
forming a layer of resin thermoset film over the prepreg trace level conductor layers over one of the layers of solid dielectric prepreg material, curing the layer of resin thermoset film to form a solid dielectric film layer, forming openings in locations corresponding to conductive film vias in the solid dielectric film layer using a laser drilling or mechanical drilling process, forming the conductive film vias in the openings in the solid dielectric film layer by filling the openings with conductor material, and forming another trace level conductor layer over the solid dielectric film layer by patterning a conductor layer on an exposed surface of the solid dielectric film layer;
mounting a first semiconductor die and a second semiconductor die over the solid dielectric film layer;
mounting the substrate to a first set of conductive leads and to a second set of conductive leads of a package substrate by forming solder joints; and
covering the substrate, the solid dielectric film layer, the first semiconductor die, the second semiconductor die, portions of the first set of conductive leads, and portions of the second set of conductive leads with mold compound.

10. The method of claim 9, wherein forming the substrate further comprises:
forming a first planar coil and a second planar coil from ones of the core trace level conductor layers, the prepreg trace level conductor layers or the another trace level conductor layer, the first planar coil and the second planar coil spaced apart by dielectric material and electrically insulated from one another.

11. The method of claim 10, wherein the first semiconductor die and the second semiconductor die are spaced from one another and wherein the first semiconductor die and the second semiconductor die are electrically insulated from one another.

12. The method of claim 11, and further comprising coupling the first semiconductor die to the first planar coil and coupling the second semiconductor die to the second planar coil.

13. The method of claim 12, wherein the first planar coil and the second planar coil are formed on opposite sides of the planar dielectric core of the substrate.

14. The method of claim 11, wherein the first planar coil and the second planar coil are arranged to inductively couple to one another and form a transformer.

15. The method of claim 10, wherein forming a layer of resin thermoset film further comprises forming a layer of Ajinomoto Build-Up Film.

16. A hybrid isolation laminate, comprising:
a substrate, comprising:
core trace level conductor layers on opposite sides of a planar dielectric core;
prepreg layers of resin impregnated glass cloth over the core trace level conductor layers on the opposite sides of the planar dielectric core;
conductive prepreg vias extending through the prepreg layers to the core trace level conductor layers on opposite sides of the planar dielectric core;
prepreg trace level conductors over the prepreg layers and contacting the conductive prepreg vias;
a layer of resin thermoset film formed over the prepreg trace level conductor layers over one of the prepreg layers, the layer of resin thermoset film cured to form a solid dielectric film layer;
film layer conductive vias extending through the solid dielectric film layer; and
another surface trace level conductor layer formed over the solid dielectric film layer on a surface of the solid dielectric film layer.

17. The hybrid isolation laminate of claim 16, wherein the layer of resin thermoset film further comprises Ajinomoto Build-Up Film.

18. The hybrid isolation laminate of claim 17 and further comprising a first planar coil and a second planar coil formed from ones of the core trace level conductors, prepreg trace level conductor layers or the another trace level conductor, the first planar coil and the second planar coil spaced by dielectric material and electrically isolated from one another.

19. The hybrid isolation laminate of claim 18, wherein the first planar coil and the second planar coil are formed on opposite sides of the planar dielectric core and are arranged to inductively couple to one another.

20. The hybrid isolation laminate of claim 19, wherein the first planar coil and the second planar coil form a transformer.

21. A microelectronics device package, comprising:
a substrate, comprising core trace level conductor layers on opposite sides of a planar dielectric core, prepreg layers of resin impregnated glass cloth over the trace level conductor layers on the opposite sides of the planar dielectric core, conductive prepreg vias extending through the prepreg layers to the core trace level conductor layers on opposite sides of the planar dielectric core, and prepreg trace level conductors over the prepreg layers and contacting the conductive prepreg vias;
a layer of resin thermoset film formed over the prepreg trace level conductor layers over one of the prepreg layers, the layer of resin thermoset film cured to form a solid dielectric film layer;
film layer conductive vias extending through the solid dielectric film layer;
another surface level conductor layer formed over the solid dielectric film layer on a surface of the solid dielectric film layer;
a first semiconductor die and a second die are flip chip mounted on the surface of the solid dielectric film layer;
the substrate mounted to a first set of conductive leads and to a second set of conductive leads of a package substrate by solder joints; and
the substrate, the solid dielectric film layer, the first semiconductor die and the second semiconductor die, portions of the first set of conductive leads, and portions of the second set of conductive leads covered with mold compound.

22. The microelectronics device package of claim 21, wherein the layer of resin thermoset film comprises a layer of Ajinomoto Build-up Film.

23. The microelectronics device package of claim 21, wherein a portion of the first set of leads and a portion of the second set of leads is exposed from and extends away from the mold compound to form terminals for the microelectronics device package.

24. The microelectronics device package of claim 21, and further comprising a first planar coil and a second planar coil formed from ones of the core trace level conductors, prepreg trace level conductor layers or the another trace level conductor, the first planar coil and the second planar coil spaced by dielectric material and electrically isolated from one another.
